(19) United States
(12) Patent Application Publication
(10) Pub. No.: US 2026/0090281 A1
(43) Pub. Date: Mar. 26, 2026

(54) FREE LAYER OF MAGNETIC TUNNEL JUNCTION, MAGNETIC MEMORY CHIP, AND METHOD FOR MANUFACTURING MAGNETIC TUNNEL JUNCTION

(71) Applicants: YANGTZE DELTA GRADUATE SCHOOL OF BEIJING INSTITUTE OF TECHNOLOGY (JIAXING), JIAXING (CN); BEIJING INSTITUTE OF TECHNOLOGY, BEIJING (CN)

(72) Inventors: SHUJUN YE, BEIJING (CN); KOICHI NISHIOKA, JIAXING (CN)

(73) Assignees: YANGTZE DELTA GRADUATE SCHOOL OF BBEIJING INSTITUTE OF TECHNOLOGY (JIAXING), JIAXING (CN); BEIJING INSTITUTE OF TECHNOLOGY, BEIJING (CN)

(21) Appl. No.: 18/951,618

(22) Filed: Nov. 18, 2024

Related U.S. Application Data
(63) Continuation of application No. PCT/CN2024/120033, filed on Sep. 20, 2024.

(51) Int. Cl. H10N 50/85; G11C 11/16; H10B 61/00; H10N 50/10

(52) U.S. Cl. CPC H10N 50/85; G11C 11/161; G11C 11/1675; H10B 61/00; H10N 50/10

(57) ABSTRACT

The present disclosure provides a structure of a free layer of a magnetic tunnel junction (MTJ), the core device of a magnetic random access memory (MRAM) chip, and a method for manufacturing the same. The free layer provided by the present disclosure includes one or more ferromagnetic film layers and a coupling superposition layer sandwiched between all the adjacent ferromagnetic film layers. During information writing, the ferromagnetic films can carry out spin reversal separately to reduce information writing energy; at the same time, because of a coupling effect of the ferromagnetic film layers, the free layer can maintain high thermal stability. Therefore, the contradiction between low information writing energy and high thermal stability, which is the current main contradiction in the large-scale application of MTJ-based MRAMs is overcome.

### TECHNICAL FIELD

The present disclosure relates to the field of memory chips in integrated circuits, in particular to a free layer of a magnetic tunnel junction, which is an important device of a new generation of non-volatile memory, i.e., a magnetic memory, a magnetic memory chip formed by the magnetic tunnel junction, and a method for manufacturing the free layer.

### BACKGROUND ART

The standby energy consumption (i.e., volatility) of random access memories (e.g., SRAMs and DRAMs) based on metal-oxide-semiconductor field-effect transistors (MOSFETs) has become increasingly severe with the small size of devices. Magnetic random access memories (MRAMs) based on spintronic device magnetic tunnel junctions (MTJs) are the most promising memory chip for large-scale application in the new generation of integrated circuits because they do not require standby energy consumption for information storage.

The MTJ forming the MRAM is formed by sandwiching two ferromagnetic films (one of which has a fixed spin direction and is called a fixed layer or a pinned layer, and the other of which has a spin direction that can be controlled to flip for information writing, and is called a free layer or a reference layer) with an insulating tunneling layer (usually MgO). The opposite and parallel spin directions of the two magnetic films create high and low resistive states, which are used to store information of 0 and 1, respectively.

Currently, the way most likely to be applied on a large scale is the use of spin transfer torque (STT) for information writing of the MTJ. The principle thereof is that spin electrons, as they are transferred from the fixed layer, pass through the insulating tunneling layer and enter the free layer or transferred from the free layer, pass through the insulating tunneling layer and enter the fixed layer, may generate a spin transfer torque that changes the spin direction of the free layer. However, the free layer of the MTJ-MRAM with the STT writing mode will face the contradiction between low information writing energy consumption and high thermal stability, which limits large-scale application thereof.

### SUMMARY

In view of the background art and problems described above, the present disclosure provides an MTJ with a free layer including a plurality of coupled ferromagnetic film layers. The ferromagnetic film layers forming the free layer are reversed separately during information writing, so that information writing energy may be significantly reduced compared to a free layer including a single ferromagnetic film layer. Furthermore, due to the coupling between the ferromagnetic film layers, the thermal stability of the free layer is not reduced. Specifically,

the present disclosure provides a magnetic tunnel junction for a magnetic memory chip, where a free layer includes one or more ferromagnetic film layers and a coupling superposition layer sandwiched between all adjacent ferromagnetic film layers to couple the adjacent ferromagnetic film layers; the coupling superposition layer includes two oxide coupling layers and a magnetic insertion layer sandwiched between the two oxide coupling layers; each of the ferromagnetic film layers contains at least one of cobalt and iron; the two oxide coupling layers are made of any one of magnesium oxides and magnesium oxides containing at least one of iron, cobalt, nickel, zinc and boron; and the magnetic insertion layer contains at least one of iron, cobalt, and nickel.

The following additions are made to the above:

the one or more ferromagnetic film layers herein generally refer to two or more ferromagnetic film layers. In the case of two ferromagnetic film layers, there is one coupling superposition layer sandwiched between both ferromagnetic film layers to couple the adjacent ferromagnetic film layers; in the case of three ferromagnetic film layers, there are two coupling superposition layers sandwiched between all the adjacent ferromagnetic film layers to couple the adjacent ferromagnetic film layers; and typically, because all adjacent ferromagnetic film layers are sandwiched with coupling superposition layers, the number of the coupling superposition layers is one less than the number of the ferromagnetic film layers in order to satisfy the above claim item. The structure of the coupling superposition layer formed by the two oxide coupling layers and the magnetic insertion layer sandwiched between the two oxide coupling layers is the most important characteristic of the present disclosure.

According to the magnetic tunnel junction with the above characteristics, the characteristics thereof are further defined as: the free layer is sandwiched between magnesium oxide film layers.

The following additions are made to the above:

the free layer is sandwiched between the two magnesium oxide film layers, the magnesium oxide film layer at one end is an insulating tunneling layer of the magnetic tunnel junction, and the magnesium oxide film layer at the other end is used to increase the perpendicular anisotropy of the free layer. The position of the magnesium oxide film layer as the insulating tunneling layer depends on the position of a fixed layer and the free layer relative to a substrate.

According to the magnetic tunnel junction with the above characteristics, the characteristics thereof are further defined as: the magnetic insertion layer contains at least one non-magnetic element of boron, silicon, aluminum, tungsten, tantalum, hafnium, zirconium, niobium, molybdenum, titanium, vanadium, chromium, palladium, and platinum; and a thickness of the magnetic insertion layer is less than 1 nanometer.

The following additions are made to the above:

The magnetic insertion layer sandwiched between the two oxide coupling layers in the coupling superposition layer is mainly used to regulate the coupling between the ferromagnetic film layers sandwiching the coupling superposition layer, so that the magnetic insertion layer may contain at least one non-magnetic element of boron, silicon, aluminum, tungsten, tantalum, hafnium, zirconium, niobium, molybdenum, titanium, vanadium, chromium, palladium, platinum, etc., in addition to at least one ferromagnetic element of iron, cobalt and nickel. In addition, the thickness of the magnetic insertion layer may not exceed 1 nanometer, otherwise a coupling effect between the ferromagnetic film layers may not be well produced.

According to the magnetic tunnel junction with the above characteristics, the characteristics thereof are further defined as: a top view of the free layer is any one of a circle with a diameter between 20 nanometers and 50 nanometers and a non-circle with an area between 310 square nanometers and 1960 square nanometers; and coupling energy between any adjacent ferromagnetic film layers of the ferromagnetic film layers is not greater than 0.5 mJ/m².

The following additions are made to the above:

The present disclosure, due to the spintronic reversal mode of the free layer during information writing, takes into account the size of the top view of the device that may satisfy the spintronic reversal mode, that is, the diameter is between 20 nanometers and 50 nanometers in the case of a circle, and the area of the top view of the device is between 310 square nanometers and 1,960 square nanometers in the case of a non-circle. Similarly, the coupling energy between any adjacent ferromagnetic film layers is not greater than 0.5 mJ/m² based on the spintronic reversal mode of the free layer during information writing.

According to the magnetic tunnel junction with the above characteristics, the characteristics thereof are further defined as: a thickness of the coupling superposition layer is greater than that of an insulating tunneling layer connecting the free layer and a fixed layer of the magnetic tunnel junction.

The following additions are made to the above:

Considering the resistance of the MTJ, the thickness of the two oxide coupling layers in the coupling superposition layer needs to be less than or equal to the thickness of the insulating tunneling layer connecting the free layer and the fixed layer, but after adding the magnetic insertion layer between the two oxide coupling layers, the thickness of the coupling superposition layer (including the two oxide coupling layers and the magnetic insertion layer sandwiched between the two oxide coupling layers) is greater than the thickness of the insulating tunneling layer connecting the free layer and the fixed layer. Since the magnetic insertion layer is typically less than 1 nanometer, the magnetic insertion layer is equivalent to a few atomic layers. Since the film actually prepared may not show clear layering using a projection electron microscope TEM, the above coupling superposition layer may actually be observed as oxide coupling layers doped with a magnetic insertion layer, or the oxide coupling layers being thickened, so there are the above limitations.

According to the magnetic tunnel junction with the above characteristics, the characteristics thereof are further defined as: the material, composition and thickness of the ferromagnetic film layers at different positions are either the same or different; the material, composition and thickness of the coupling superposition layers at different positions are either the same or different; the material, composition and thickness of the oxide coupling layers at different positions are either the same or different; and the material, composition and thickness of the magnetic insertion layers at different positions are either the same or different.

The following additions are made to the above:

Because the present disclosure is intended to use a plurality of mutually coupled ferromagnetic film layers instead of a conventional single ferromagnetic film layer as the free layer of the magnetic tunnel junction, the variations in material, composition and thicknesses of the ferromagnetic film layers, the coupling superposition layers, the oxide coupling layers, and the magnetic insertion layers are precisely used to regulate the coupling of the plurality of ferromagnetic film layers, so that the spin reversal of each film layer is controlled to reduce the information writing energy, and thermal stability is maintained to a certain extent.

A method for manufacturing the magnetic tunnel junction for a magnetic memory chip according to all the claim items described above includes the following main steps:
(1.1) preparing a first magnesium oxide film layer;
(1.2) preparing a first ferromagnetic film layer with a magnetization direction perpendicular to a film surface on one side of the first magnesium oxide film layer;
(1.3) preparing a first oxide coupling layer on an adjacent side of the first ferromagnetic film layer opposite the first magnesium oxide film layer;
(1.4) preparing a first magnetic insertion layer on an adjacent side of the first oxide coupling layer opposite the first ferromagnetic film layer;
(1.5) preparing a second oxide coupling layer on an adjacent side of the first magnetic insertion layer opposite the first oxide coupling layer;
(1.6) preparing a second ferromagnetic film layer with a magnetization direction perpendicular to a film surface on an adjacent side of the second oxide coupling layer opposite the first magnetic insertion layer; and
(1.7) preparing a second magnesium oxide film layer on an adjacent side of the second ferromagnetic film layer opposite the second oxide coupling layer.

The following additions are made to the above:

The manufacturing method described above is intended to manufacture the free layer portion of the magnetic tunnel junction. During the actual manufacturing process, the MTJ may be prepared in a post-engineered BEOL of a CMOS logic circuit or directly on a wafer. Alternatively, the free layer of the MTJ may be prepared either first or later.

Based on the aforementioned manufacturing method, the characteristics thereof are further defined as: after step (1.6), steps (1.3) to (1.6) are repeated to form a structure in which a plurality of coupling superposition layers are alternately superimposed with a plurality of ferromagnetic film layers.

The following additions are made to the above:

Steps (1.3) to (1.6) are repeated herein to form the structure in which the plurality of coupling superposition layers are alternately superimposed with the plurality of ferromagnetic film layers, but structures formed multiple times may be the same or different.

Based on the aforementioned manufacturing method, the characteristics thereof are further defined as: the ferromagnetic film layers are formed by any one of film deposition methods of co-sputtering with other targets, alternating sputtering with other targets, and sputtering after directly adding cobalt and iron into other targets for doping.

Based on the aforementioned manufacturing method, the characteristics thereof are further defined as: the oxide coupling layers are formed by any one of film deposition methods of co-sputtering with other targets, alternating sputtering with other targets, and sputtering after directly adding cobalt and iron into other targets for doping.

Based on the aforementioned manufacturing method, the characteristics thereof are further defined as: the magnetic insertion layers are formed by any one of film deposition methods of co-sputtering with other targets, alternating sputtering with other targets, and sputtering after directly adding cobalt and iron into other targets for doping.

The methods for manufacturing the ferromagnetic film layers, the oxide coupling layers, and the magnetic insertion layers are limited by the above-described claim items respectively.

The present disclosure has the following effects: the free layer includes a plurality of ferromagnetic film layers, and the ferromagnetic layers sequentially undergo magnetic reversal one by one, so that the information writing current of the device is significantly reduced. At the same time, by regulating coupling between the plurality of ferromagnetic film layers, it can be ensured that the thermal stability is improved. The higher the current (voltage), the more easily the MgO insulating tunneling layer is destroyed. Therefore, the present disclosure can also significantly improve the endurance of the insulating tunneling layer of the MTJ, and accordingly the endurance of the device is improved.

### BRIEF DESCRIPTION OF THE DRAWINGS

FIG. 1 is one of the embodiments of the present disclosure, and shows a basic structure of a free layer including two ferromagnetic film layers of which magnetic coupling is regulated by a magnetic insertion layer and a coupling superposition layer sandwiched between the two ferromagnetic film layers.

FIG. 2 is one of the embodiments of the present disclosure, and shows a basic structure formed by sandwiching the basic structure in FIG. 1 between two magnesium oxide film layers.

FIG. 3 is one of the embodiments of the present disclosure, and shows a basic structure of a free layer including three ferromagnetic film layers of which magnetic coupling is regulated by a magnetic insertion layer, and coupling superposition layers sandwiched between the ferromagnetic film layers.

FIG. 4 is one of the embodiments of the present disclosure, and shows a basic structure of a free layer including four ferromagnetic film layers of which magnetic coupling is regulated by a magnetic insertion layer and coupling superposition layers sandwiched between the ferromagnetic film layers,

FIG. 5 is one of the embodiments of the present disclosure, and shows a basic structure of a free layer including two ferromagnetic film layers of which magnetic coupling is regulated by a magnetic insertion layer and a coupling superposition layer sandwiched between the two ferromagnetic film layers. The difference from FIG. 1 is that the magnetic insertion layer and oxide coupling layers sandwiching the magnetic insertion layer are not clearly distinguishable because the magnetic insertion layer is thin, but the coupling superposition layer is clearly thicker than an insulating tunneling layer.

FIG. 6 is one of the embodiments of the present disclosure and is the same as FIG. 5, except that a free layer includes three ferromagnetic film layers.

FIG. 7 is one of the embodiments of the present disclosure and is the same as FIG. 5, except that a free layer includes four ferromagnetic film layers.

FIG. 8 is one of the embodiments of the present disclosure, and shows a schematic diagram of conflicts among thermal stability, information writing energy, and endurance faced by an MRAM with a free layer including a single ferromagnetic film layer.

FIG. 9 is one of the embodiments of the present disclosure, and shows a schematic diagram of a free layer including two ferromagnetic film layers of which magnetic coupling is regulated by a magnetic insertion layer and a coupling superposition layer sandwiched between the two ferromagnetic film layers.

FIG. 10 is one of the embodiments of the present disclosure, and shows a magnetic reversal mode of the free layer including the two ferromagnetic film layers in FIG. 9 subjected to an external current when a magnetic coupling between the two ferromagnetic film layers is strong.

FIG. 11 is one of the embodiments of the present disclosure, and shows one of magnetic reversal modes of the free layer including the two ferromagnetic film layers in FIG. 9 subjected to an external current when a magnetic coupling between the two ferromagnetic film layers is weak.

FIG. 12 is one of the embodiments of the present disclosure, and shows one of magnetic reversal modes of the free layer including the two ferromagnetic film layers in FIG. 9 subjected to an external current when a magnetic coupling between the two ferromagnetic film layers is weak.

FIG. 13 is one of the embodiments of the present disclosure, and shows a relationship between an information writing current and a required reversal time for the device with the structure of FIG. 9 calculated when J_{cpl} is 0.3 mJ/m² (two free layers are reversed separately) and 1.0 mJ/m² (two free layers are reversed integrally), assuming that the ferromagnetic film layers have a thickness of 1.5 nanometers and a diameter of 30 nanometers. The results show that the writing current may be significantly reduced during separated reversals.

FIG. 14 is one of the embodiments of the present disclosure, and shows reversal modes of points A, B, and C on a curve of an information writing current versus required reversal current time when J_{cpl} is 0.3 mJ/m² (the two free layers are reversed separately) in FIG. 13 on magnetization curves on an X axis and a Z axis, which correspond to Phase 2 and Phase 3 in FIGS. 11 and 12, respectively.

FIG. 15 is one of the embodiments of the present disclosure, and shows reversal modes of points D, E, and F on a curve of an information writing current versus required reversal current time when J_{cpl} is 1.0 mJ/m² (the two free layers are reversed integrally) in FIG. 13 on magnetization curves on an X axis and a Z axis, which correspond to Phase 4 in FIG. 10.

FIG. 16 is one of the embodiments of the present disclosure, and shows a relationship between thermal stability Δ and coupling energy deduced from empirical formulas when it is assumed that the ferromagnetic film layers in the device with the structure of FIG. 9 have a thickness of 1.5 nanometer, a diameter of 30 nanometer, and effective magnetic anisotropy energy of 0.52 mJ/m², indicating that when J_{cpl} is 0.3 mJ/m², the thermal stability Δ is greater than 90, which satisfies the utilization requirements of MRAMs.

### DETAILED DESCRIPTION OF THE INVENTION

The present disclosure is described below in conjunction with the accompanying drawings and by way of example of implementations.

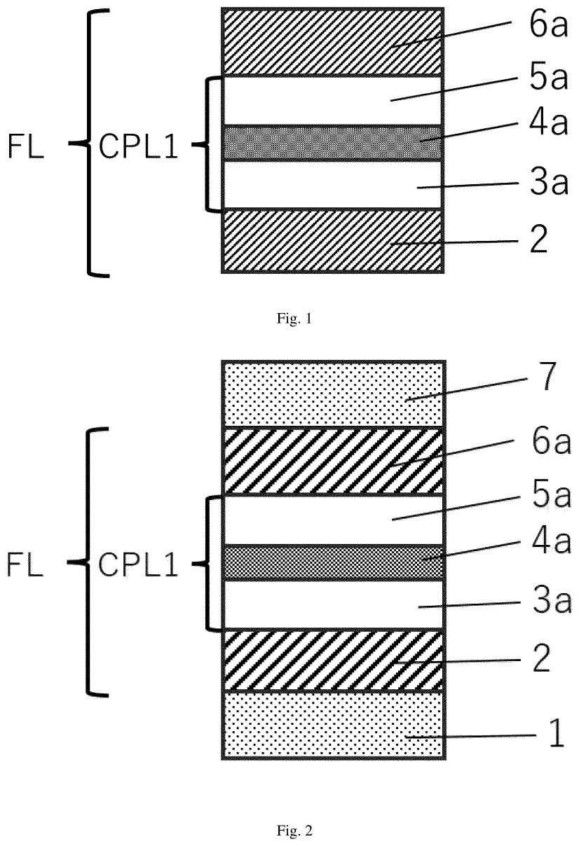

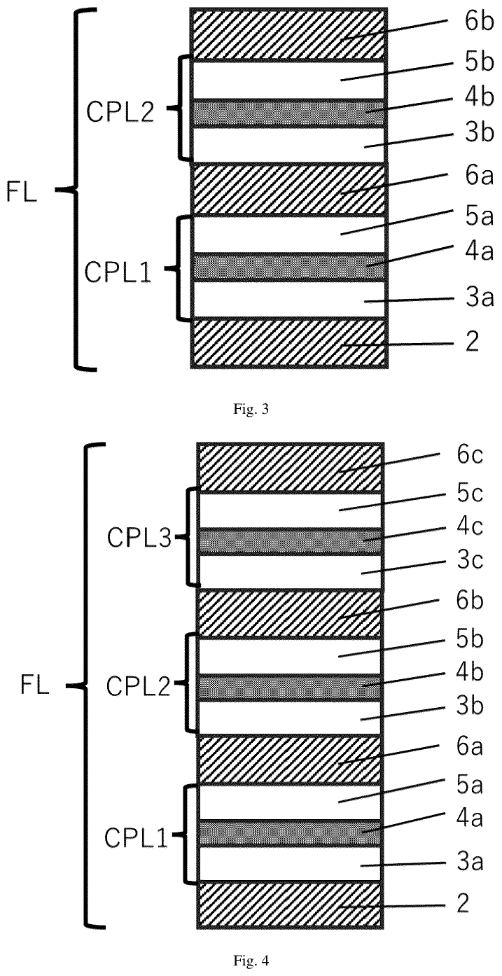

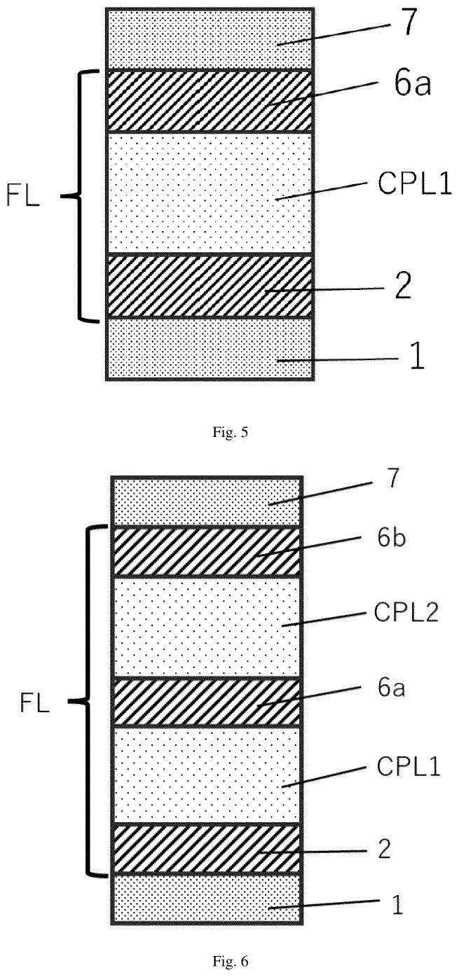

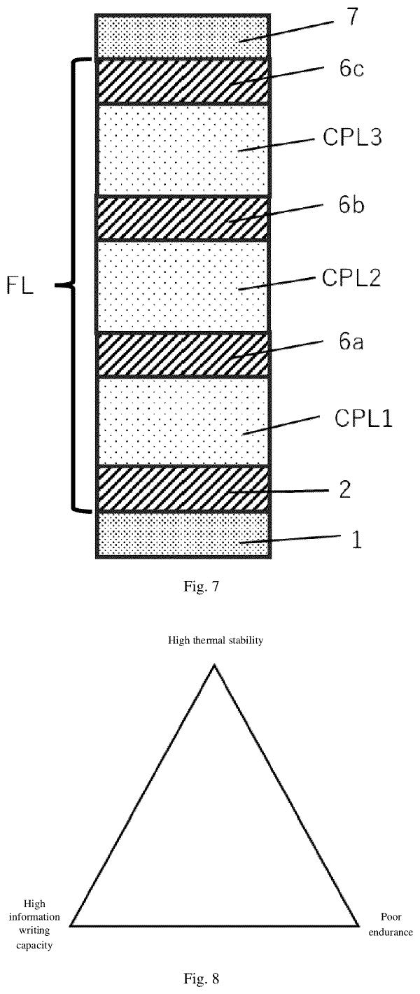

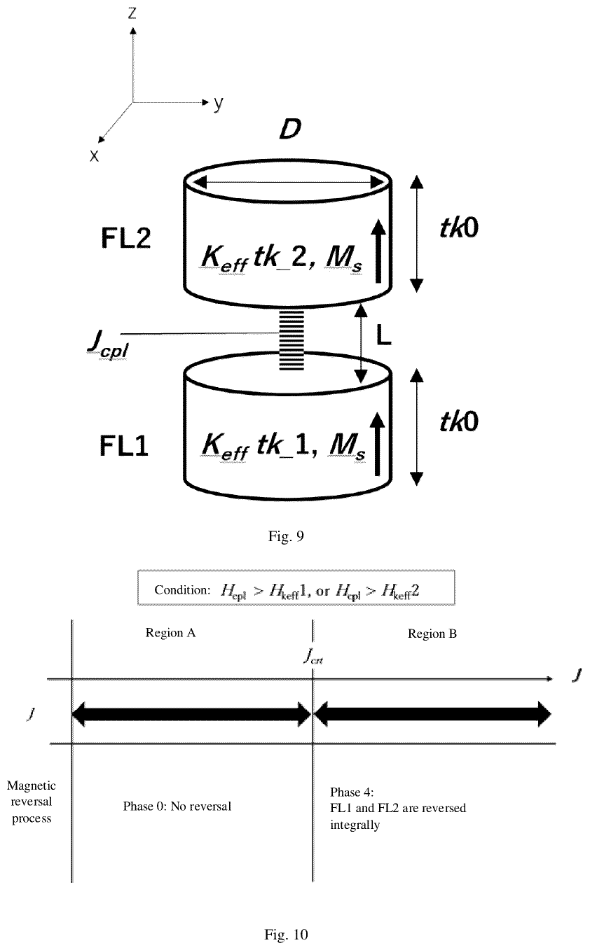

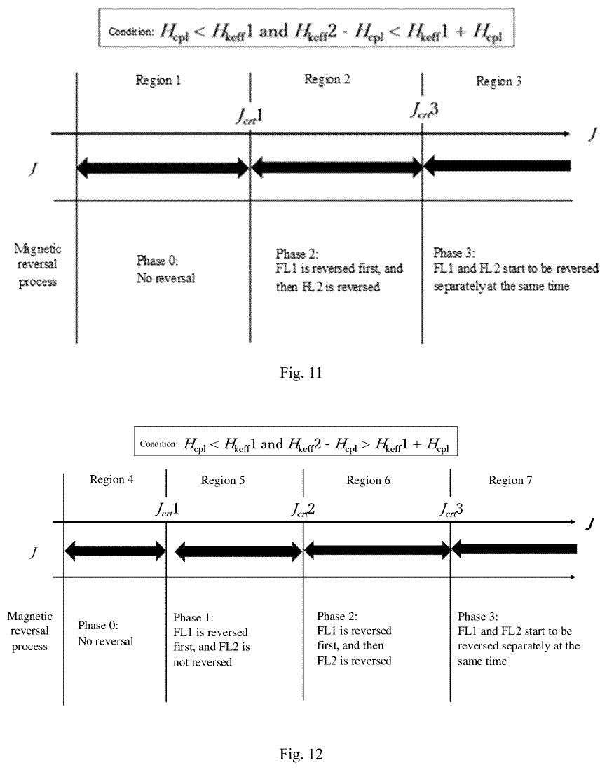

FIG. 1 is one of the embodiments of the present disclosure, and shows a basic structure of a free layer (FL) including two ferromagnetic film layers of which magnetic coupling is regulated by a magnetic insertion layer and a coupling superposition layer sandwiched between the two ferromagnetic film layers, where 2 and 6 denote ferromagnetic film layers, 3a and 5a denote oxide coupling layers, and 4a denotes a magnetic insertion layer. The oxide coupling layers 3a and 5a and the magnetic insertion layer 4a form a coupling superposition layer CPL1. The ferromagnetic film layers (2 and 6) contain at least one of cobalt and iron; the two oxide coupling layers (3a and 5a) are made of magnesium oxides and any one of magnesium oxides containing at least one of iron, cobalt, nickel, zinc, and boron; and the magnetic insertion layer 4a contains at least one of iron, cobalt, and nickel.

FIG. 2 is one of the embodiments of the present disclosure, and shows a structure formed by sandwiching the basic structure of the free layer FL in FIG. 1 between two magnesium oxide film layers 1 and 7. The magnesium oxide film layer at one end is an insulating tunneling layer of the magnetic tunnel junction, and the magnesium oxide film layer at the other end is used to increase the perpendicular anisotropy of the free layer. The position of the magnesium oxide film layer as the insulating tunneling layer depends on the position of a fixed layer and the free layer relative to a substrate.

FIG. 3 is one of the embodiments of the present disclosure, and shows a basic structure of a free layer including three ferromagnetic film layers (2, 6a and 6b) of which magnetic coupling is regulated by a magnetic insertion layer, and coupling superposition layers (CPL1 and CPL2) sandwiched between the ferromagnetic film layers. 3a and 5a are oxide coupling layers, and form the coupling superposition layer CPL1 with the magnetic insertion layer 4a sandwiched therebetween. 3b and 5b are oxide coupling layers, and form the coupling superposition layer CPL2 with the magnetic insertion layer 4b sandwiched therebetween.

FIG. 4 is one of the embodiments of the present disclosure, and shows a basic structure of a free layer including four ferromagnetic film layers (2, 6a, 6b and 6c) of which magnetic coupling is regulated by a magnetic insertion layer, and coupling superposition layers (CPL1, CPL2 and CPL3) sandwiched between the ferromagnetic film layers. Compared with FIGS. 3, 3c and 5c are added as oxide coupling layers, and form the coupling superposition layer CPL3 with the magnetic insertion layer 4c sandwiched therebetween.

FIG. 5 is one of the embodiments of the present disclosure, and shows a basic structure of a free layer including two ferromagnetic film layers of which magnetic coupling is regulated by a magnetic insertion layer and a coupling superposition layer sandwiched between the two ferromagnetic film layers. The difference from FIG. 2 is that the magnetic insertion layer and the oxide coupling layers sandwiching the magnetic insertion layer are not clearly distinguishable because the magnetic insertion layer is thin, but the coupling superposition layer (CPL1) is clearly thicker than the insulating tunneling layer (1 or 7). FIG. 6 and FIG. 7 are essentially similar to FIG. 5, and show a basic structure of a free layer including three ferromagnetic film layers and coupling superposition layers sandwiched therebetween and a basic structure of a free layer including four ferromagnetic film layers and coupling superposition layers sandwiched therebetween, respectively.

FIG. 8 is one of the embodiments of the present disclosure, and shows a schematic diagram of conflicts among thermal stability, information writing energy, and endurance faced by an MRAM with a free layer including a single ferromagnetic film layer. For the MRAM with the free layer including the single ferromagnetic film layer, the higher the thermal stability, the higher the information writing energy consumption required, i.e., the higher the writing current. The information writing current also has a high voltage on the insulating tunneling layer, which makes the insulating tunneling layer prone to breaking through and reduces endurance. The following are thermal stability and data storage retention.

As a memory, the MRAM is typically required to be able to retain data for 10 years in the range of −25° C. to 125° C., that is, the data storage retention is 10 years. In the case where the free layer is a single ferromagnet, the thermal stability constant Δ is given by the following equation:

$$Δ = {E}_{b} / ( {k}_{B} T ) = {K}_{eff} V / ( {k}_{B} T ) ; V = ( π / 4 ) {D}^{2} tk \qquad ( 1 )$$

In equation (1), E_{b} denotes an energy barrier between states “0” and “1” of the free layer, k_{B} denotes the Boltzmann's constant, T denotes an absolute temperature, K_{eff} denotes the effective perpendicular magnetic anisotropy energy per unit volume, D denotes the diameter of the free layer, tk denotes the thickness of the free layer, and K_{eff} V denotes the effective magnetic anisotropy energy of the free layer.

In equation (1), the thermal stability constant Δ is directly proportional to K_{eff} V, i.e. the effective magnetic anisotropy energy of the free layer. Since the magnetic anisotropy decreases with increasing temperature, the thermal stability constant Δ is lowest at high temperature. Thus, in order to ensure thermal stability, the thermal stability at high temperature needs to be ensured. For an STT-MTJ, as a rule of thumb, in order to retain data for 10 years, the thermal stability constant Δ at room temperature needs to be 90 or more.

In addition, MRAM chips require information to be written 10¹⁶ times in the range of −25° C. to 125° C. without degradation, i.e., the endurance is greater than 10¹⁶ times. The main influencing factor of the information writing current is the effective perpendicular magnetic anisotropy of the free layer. According to the literature 1 (J. Z. Sun “Spin-current interaction with amonodomain magnetic body: A model study”, Phys. Rev. B vol. 62, pp 570-578 (2000)), it is deduced that the magnitude of a spin-current comparable to the effective magnetic field of electron spin-induced magnetic reversal may be calculated as follows:

$${h}_{s} = - ( 1 / 2 ) ( ℏ / e ) η J / ( 2 {K}_{eff} tk ) \qquad ( 2 a )$$

where h denotes the Dirac constant, e denotes electron charges, η denotes the spin polarization rate, J denotes the current density, and K_{eff} tk denotes the effective magnetic anisotropy energy of the free layer of the MTJ device. The magnetic reversal produced by the spin-current is:

$$θ ( τ ) = {θ}_{0} exp ( - τ / {τ}_{1} ) , 1 / {τ}_{1} = α + {h}_{s} \qquad ( 2 b )$$

where τ is proportional to the time t(sec) called natural time unit. As seen in equation (2b),

the magnetic reversal of the free layer must satisfy 1/τ₁<0 and α+hₛ<0. That is, hₛ is negative (the current density J<0), and an absolute value thereof is larger than the magnetic damping constant α. Moreover, the larger the absolute value thereof, the larger −1/τ₁, thereby achieving high-speed magnetic reversal.

As seen in equation (2a), hₛ is inversely proportional to the effective magnetic anisotropy energy K_{eff} tk per unit area of the free layer. The larger K_{eff} tk is, the more difficult it is to perform information writing, i.e., the larger the current (voltage) is during information writing.

In summary, the issue for improvement in the MTJ is to reduce the current (voltage) during information writing while maintaining the thermal stability constant Δ of the free layer to be 90 or more.

FIG. 9 is one of the embodiments of the present disclosure, and shows a schematic diagram of a free layer including two ferromagnetic film layers of which magnetic coupling is regulated by a magnetic insertion layer and a coupling superposition layer sandwiched between the two ferromagnetic film layers (FL1 and FL2). The two ferromagnet film layers FL1 and FL2 in FIG. 9 have a diameter D and a thickness tk0, and have common magnetization Mₛ and effective perpendicular magnetic anisotropy energies K_{eff1} and K_{eff2} per unit volume. The magnetic coupling energy per unit area between FL1 and FL2 is J_{cpl}. Then it can be defined in terms of magnetic properties all as follows:

$${H}_{cpl} = {J}_{cpl} / ( {M}_{s} tk 0 ) ; {H}_{keff} 1 = 2 {K}_{eff} 1 / {M}_{s} ; {H}_{keff} 2 = 2 {K}_{eff} 2 / {M}_{s} .$$

FIGS. 10, 11, and 12 below show magnetic reversal modes calculated based on the model of FIG. 9, with reference to literature 2 (K. Nishioka et. al., “Effect of Magnetic Coupling between two CoFeB layers on Thermal Stability in Perpendicular Magnetic Tunnel Junctions with MgO/CoFeB/Insertion Layer/CoFeB/MgO”, IEEE Transactions on Magnetics 58(2), 1-6, 2021).

FIG. 10 shows a magnetic reversal mode of the free layer including the two ferromagnetic film layers in FIG. 9 subjected to an external current when magnetic coupling between the two ferromagnetic film layers is strong. In region A, the current density J is less than the critical current density J_{crt}, and neither FL1 nor FL2 may undergo a magnetic reversal (Phase 0). In region B where J>J_{crt} is satisfied, FL1 and FL2 undergo an integrated magnetic reversal (Phase 4), and the reversal speed may be calculated according to equation (5). The larger the current density J, the larger the magnetic reversal speed. The conditions of FIG. 10 are: H_{cpl}>H_{keff1} and H_{cpl}>H_{keff}2, magnetization between FL1 and FL2 is always parallel, and because of the presence of strong magnetic coupling, the two ferromagnets become one. The current-generated magnetic reversal may be expressed by the following equation:

$$d θ / d τ = - θ ( α + {h}_{s} ) ; d φ / d τ = - 1 + α + {h}_{s} \qquad ( 3 )$$

where τ denotes time known as natural time unit, hₛ denotes the effective magnetic field of the spin-current, and a denotes the magnetic damping coefficient of the two ferromagnets, with the usual value of a being 0.013. τ is represented by the following three equations (equation 4).

$$τ = {Ω}_{k} ( t ) / ( 1 + {α}^{2} ) ; {Ω}_{k} = γ {H}_{keff} ; {H}_{keff} = ( {H}_{keff} 1 + {H}_{keff} 2 ) / 2 \qquad ( 4 )$$

where γ denotes a magnetic reversal ratio, Ωₖ denotes the ferromagnetic resonance frequency, and H_{keff} denotes an effective perpendicular magnetic anisotropic field.

$$θ ( τ ) = {θ}_{0} exp ( - τ / {τ}_{1} ) , 1 / {τ}_{1} = α + {h}_{s} ; dp ( τ ) = ( - 1 + α + {h}_{s} ) τ \qquad ( 5 )$$

The effective magnetic field hₛ generated by the spin-current is directly proportional to the current density J and inversely proportional to the effective perpendicular magnetic anisotropy field H_{keff} as shown in equation (6).

$${h}_{s} = - ( ℏ / 2 e ) η J / ( {H}_{keff} {M}_{s} ( 2 tk 0 ) \qquad ( 6 )$$

where h denotes the Dirac constant, e denotes electron charges, and η denotes a magnetic polarization rate of an electron spin for the current density J, usually taken as 0.5. As seen from equation (5), in order to achieve the magnetic reversal, 1/τ₁ must be negative, and the greater the absolute value of the negative, the faster the reversal. So hₛ<−α is required.

Thus, the critical current density J_{crt} for determining whether there is a magnetization reversal or not may be defined in terms of hₛ=−α, in which case

$${J}_{crt} = ( α / η ) ( 2 e / ℏ ) ( {H}_{keff} ) ( 2 {M}_{s} tk 0 ) \qquad ( 7 )$$

FIGS. 11 and 12 are two embodiments of the present disclosure, respectively, and show magnetic reversal modes of the free layer including the two ferromagnetic film layers in FIG. 9 subjected to an external current when magnetic coupling between the two ferromagnetic film layers is weak. The magnetization reversal of FIG. 11 needs to satisfy: H_{cpl}<H_{keff}1, H_{keff}2−H_{cpl}<H_{keff}1+H_{cpl}.

The magnetization reversal in FIG. 12 needs to satisfy: H_{cpl}<H_{keff}1, H_{keff}1+H_{cpl}<H_{keff}2−H_{cpl}. This is specified as follows:

The magnetization reversal process is more complicated in the case where the magnetic coupling magnetic field H_{cpl} is smaller than the anisotropic magnetic field H_{keff}1 (H_{cpl}<H_{keff}1), and the effective magnetic fields of FL1 and FL2 during the reversal of the spin-current are as follows:

$${h}_{s} 1 = - ( ℏ / 2 e ) η J / ( {H}_{keff} 1 M tk 0 ) ; \qquad ( 8 )$$

$${h}_{s} 2 = - ( ℏ / 2 e ) η J / ( {H}_{keff} 2 M tk 0 ) .$$

The normalized magnetic couplings of FL1 and FL2 are defined by h1 and h2, respectively. When the magnetizations of FL1 and FL2 are parallel, the magnetic couplings are positive magnetic couplings and may be expressed by the following equation:

$$h 1 = {H}_{cpl} / {H}_{keff} 1 ; h 2 = {H}_{cp 1} / {H}_{keff} 2 \qquad ( 9 )$$

When the magnetizations of FL1 and FL2 are antiparallel, the magnetic couplings are negative magnetic couplings and may be expressed by the following equation:

$$h 1 = - {H}_{cpl} / {H}_{keff} 1 ; h 2 = - {H}_{cp 1} / {H}_{keff} 2 \qquad ( 10 )$$

The magnetization reversal mode in FIG. 11 presupposes that |h1| and |h2| are both smaller than 1, and orientations (θ1, φ1) and (θ2, φ2) of respective magnetic momentums of FL1 and FL2 are determined by the following equation:

$$d θ 1 / d τ 1 = - θ1 [ α ( 1 + h 1 ) + {h}_{s} 1 ] ; \qquad ( 11 )$$

$$d θ 2 / d τ 2 = - θ2 [ α ( 1 + h 2 ) + {h}_{s} 2 ] d φ ;$$

$$1 / d τ 1 = - ( 1 + h 1 ) + α {h}_{s} 1 ;$$

$$d φ 2 / d τ 2 = - ( 1 + h 2 ) + α {h}_{s 2} 1$$

where τ1 and τ2 denote times of the natural time unit of FL1 and FL2, respectively, and hₛ1 and hₛ2 denote the effective magnetic fields generated by the spin-current of FL1 and FL2 in equation (8). τ1 and τ2 may be expressed as:

$$τ 1 = {Ω}_{k} 1 t / ( 1 + {α}^{2} ) , τ 2 = {Ω}_{k} 2 t / ( 1 + {α}^{2} ) ; \qquad ( 12 )$$

$${Ω}_{k} 1 = γ {H}_{keff} 1 , {Ω}_{k} 2 = γ {H}_{keff} 2.$$

The solutions to the above equation are:

$$θ ( τ 1 ) = {θ}_{0} exp ( - τ 1 / {τ}_{1} \_ 1 ) , 1 / {τ}_{1} \_ 1 = α ( 1 + h 1 ) + {h}_{s} 1 ; \qquad ( 13 )$$

$$φ ( τ 1 ) = [ - ( 1 + h 1 ) + α {h}_{s} 1 ] τ 1 ;$$

$$θ ( τ 2 ) = {θ}_{0} exp ( - τ 2 / {τ}_{1} \_ 2 ) , 1 / {τ}_{1} \_ 2 = α ( 1 + h 2 ) + {h}_{s} 2 ;$$

$$φ ( τ 2 ) = [ - ( 1 + h 2 ) + α {h}_{s} 2 ] τ 2$$

(−τ1/τ₁_1) (−τ2/τ₁_2) of equation (13) needs to be positive for the magnetic reversal of FL1 and FL2. Therefore, (α+h1)+hₛ1 and (α+h2)+hₛ2 need to be negative when FL1 and FL2 are reversed. That is, hₛ1<−α(1+h1), and hₛ2<−α(1+h2).

The magnetic reversal modes of the two ferromagnetic film layers in FIG. 11 and FIG. 12: when the external current is very small, FL1 and FL2 are not reversed, which is called Phase 0; when the external current is increased, it can be classified into the following three conditions of Phase 1, Phase 2, and Phase 3, according to the magnetic coupling condition:

Phase 1: FL1 is magnetically reversed and FL2 is not reversed

As seen from equation (9) and equation (10), the values of h1 and h2 change from positive to negative when FL1 is reversed.

$$h 1 : {H}_{cpl} / {H}_{keff} 1 ⟶ - {H}_{cpl} / {H}_{keff} 1 ; \qquad ( 14 )$$

$$h 2 : {H}_{cpl} / {H}_{keff} 2 ⟶ - {H}_{cpl} / {H}_{keff} 2.$$

The following conditions need to be satisfied for FL1 to be reversed and FL2 not to be reversed:

the condition for FL1 to be reversed:

$${h}_{s} 1 = - ( h / 2 e ) {r}_{i} J / ( {H}_{keff} 1 Mtk 0 ) < - α ( 1 + h 1 ) ; h 1 = + {H}_{cpl} / {H}_{keff} 1 ;$$

the condition for FL2 not to be reversed:

$${h}_{s} 2 = - ( h / 2 e ) {r}_{i} J / ( {H}_{keff} 2 Mtk 0 ) > - α ( 1 + h 2 ) ; h 2 = - {H}_{cpl} / {H}_{keff} 2. \qquad ( 15 )$$

Therefore, the following conditions need to be satisfied for Phase 1:

$${J}_{crt} 1 < J < {J}_{crt} 2 \qquad ( 16 )$$

where J_{crt}1, J_{crt}2 and J_{crt}3 are defined using the following equations.

$${J}_{crt} 1 = ( α / {r}_{i} ) ( 2 e / h ) ( Mtk 0 ) ( {H}_{keff} 1 + {H}_{cpt} ) \qquad ( 16 a )$$

$${J}_{crt} 2 = ( α / {r}_{i} ) ( 2 e / h ) ( Mtk 0 ) ( {H}_{keff} 2 - {H}_{cpt} ) \qquad ( 16 b )$$

$${J}_{crt} 3 = ( α / {r}_{i} ) ( 2 e / h ) ( Mtk 0 ) ( {H}_{keff} 2 + {H}_{cpt} ) \qquad ( 16 c )$$

Phase 2: FL1 is reversed first, and then FL2 is reversed

The state where FL2 is not reversed while FL1 is reversed, but FL2 is reversed after FL1 is reversed is called Phase 2.

The condition for FL1 to be reversed:

$${h}_{s} 1 = - ( h / 2 e ) {r}_{i} J / ( {H}_{keff} 1 Mtk 0 ) < - α ( 1 + h 1 ) ;$$

$$h 1 = + {H}_{cpl} / {H}_{keff} 1.$$

The condition for F2 not to be reversed:

$${h}_{s} 2 = - ( h / 2 e ) {r}_{i} J / ( {H}_{keff} 2 Mtk 0 ) > - α ( 1 + h 2 ) ; \qquad ( 17 )$$

$$h 2 = + {H}_{cpl} / {H}_{keff} 2.$$

The conditions for FL2 to be magnetically reversed after FL1 is magnetically reversed are as follows: the condition for FL2 to be reversed is:

$${h}_{s} 2 = - ( h / 2 e ) {r}_{i} J / ( {H}_{keff} 2 Mtk 0 ) < - α ( 1 + h 2 ) , h 2 = - {H}_{cpl} / {H}_{keff} 2. \qquad ( 18 )$$

Therefore, the following conditions need to be satisfied for Phase 2:

$${J}_{crt} 1 , {J}_{crt} 2 < J < {J}_{crt} 3 \qquad ( 19 )$$

Phase 3: FL1 and FL2 start to be reversed at the same time, but do not finish reversing at the same time.

The magnetic coupling between FL1 and FL2 is not as strong as integrated reversal. Since FL1 and FL2 are not integrally reversed, FL1 and FL2 keep the interaction to be reversed separately and do not finish the reversals at the same time. The following relationship needs to be satisfied:

The condition for FL1 to be reversed:

$${h}_{s} 1 = - ( h / 2 e ) {r}_{i} J / ( {H}_{keff} 2 Mtk 0 ) < - α ( 1 + h 1 ) , h 1 = + {H}_{cpl} / {H}_{keff} 1$$

The condition for FL2 to be reversed:

$${h}_{s} 2 = - ( h / 2 e ) {r}_{i} J / ( {H}_{keff} 2 Mtk 0 ) < - α ( 1 + h 2 ) , h 2 = - {H}_{cpl} / {H}_{keff} 2$$

The following condition needs to be satisfied for Phase 3:

$${J}_{crt} 3 < J . \qquad ( 20 )$$

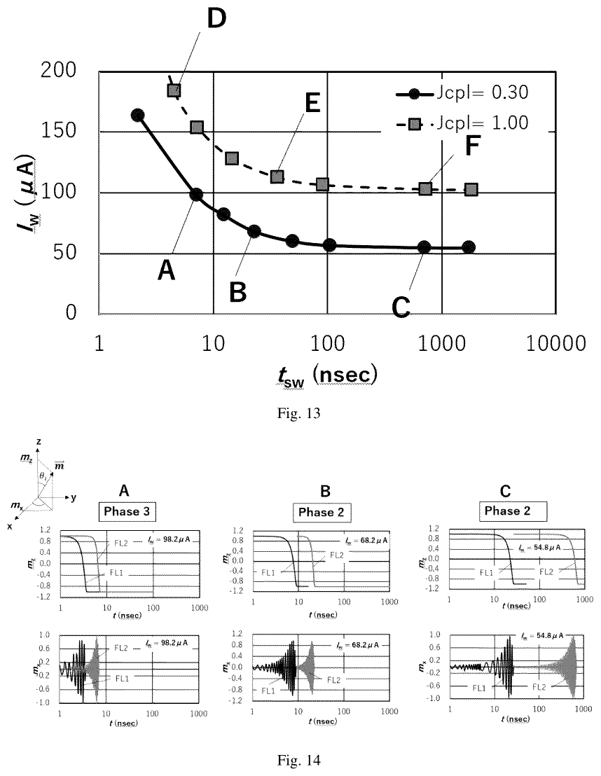

FIG. 13 is one of the embodiments of the present disclosure, and shows a relationship between an information writing current (I) and a reversal time (t_{sw}) of a device of the structure of FIG. 9 calculated when J_{cpl} is 0.3 mJ/m² (two free layers are reversed separately) and 1.0 mJ/m² (two free layers are reversed integrally), assuming that the ferromagnetic film layers have a thickness of 1.5 nanometers and a diameter of 30 nanometers. The results show that the writing current may be significantly reduced during separated reversals.

FIG. 14 is one of the embodiments of the present disclosure, and shows reversal modes of points A, B, and C on a curve of an information writing current versus required reversal time when J_{cpl} is 0.3 mJ/m² (the two free layers are reversed separately) in FIG. 13 on magnetization curves on an X axis and a Z axis, where A corresponds to Phase 2, and B and C correspond to Phase 3. From the results, it can be seen that at a writing current of 98.2 microamps, FL1 and FL2 start to be reversed separately at the same time according to Phase 3, and the reversals may be completed within 10 nanoseconds. The current is decreased, FL1 is reversed first and then FL2 is reversed according to Phase 2, in this case, the required reversal current time is prolonged.

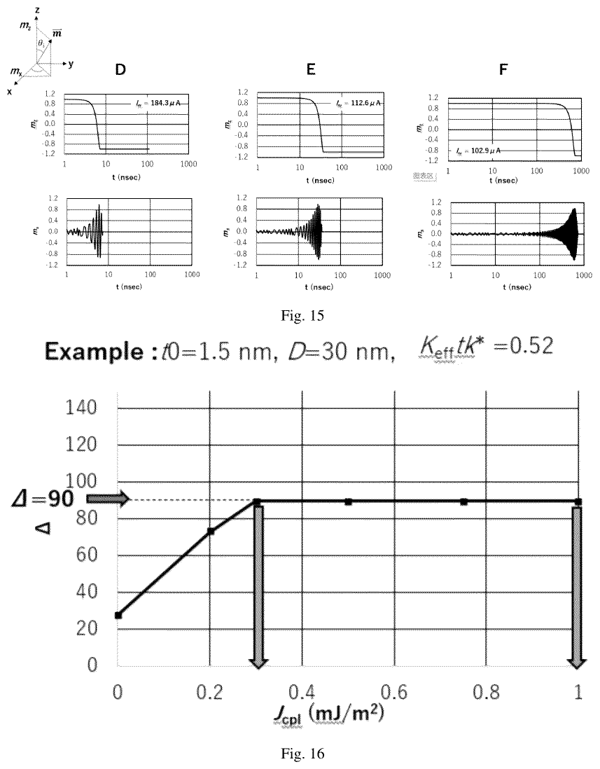

FIG. 15 is one of the embodiments of the present disclosure, and shows reversal modes of points D, E, and F on a curve of an information writing current versus required reversal time when J_{cpl} is 1.0 mJ/m² (the two free layers are reversed integrally) in FIG. 13 on magnetization curves on an X axis and a Z axis, which correspond to Phase 4 in FIG. 10, that is, FL1 and FL2 are reversed integrally. In this case, a writing current of 184.3 microamps is required to accomplish the reversal within 10 nanoseconds. This writing current is almost twice as much as the current (98.2 microamps) required for the separate reversals of the two free layers started at the same time at Phase 3 when J_{cpl} is 0.3 mJ/m² in FIG. 14. Thus, for the magnetic tunnel junction with the structure of the present disclosure, i.e., the free layer includes a plurality of ferromagnetic film layers, by adjusting the magnetic coupling between the ferromagnetic layers to make the ferromagnetic films are reversed separately, the information writing current may be substantially reduced compared to a conventional free layer including a large ferromagnetic film layer, and accordingly the endurance of the magnetic tunnel junction (MTJ) may also be substantially improved.

FIG. 16 is one of the embodiments of the present disclosure, and shows a relationship between thermal stability Δ and coupling energy deduced from empirical formulas when it is assumed that the ferromagnetic film layers in the device with the structure of FIG. 9 have a thickness of 1.5 nanometer, a diameter of 30 nanometer, and effective magnetic anisotropy energy of 0.52 mJ/m², indicating that when J_{cpl} is 0.3 mJ/m², the thermal stability Δ is greater than 90, which satisfies the utilization requirements of MRAMs. Thus, the effects of the present disclosure are further confirmed: while maintaining high thermal stability, the information writing current is reduced, and the endurance of the magnetic tunnel junction (MTJ) is improved.

All the above embodiments only express certain implementations of the present disclosure, are described in a specific manner, but are not to be construed as a limitation of the scope of the patent of invention. It should be pointed out that, for a person of ordinary skill in the art, several deformations and improvements can be made without departing from the conception of the present disclosure, all of which fall within the scope of protection of the present disclosure. Therefore, the scope of protection of the patent of invention shall be subject to the appended claims.

1. A magnetic tunnel junction for a magnetic memory chip, wherein a free layer comprises one or more ferromagnetic film layers and a coupling superposition layer sandwiched between all adjacent ferromagnetic film layers to couple the adjacent ferromagnetic film layers; the coupling superposition layer comprises two oxide coupling layers and a magnetic insertion layer sandwiched between the two oxide coupling layers; the ferromagnetic film layers contain at least one of cobalt and iron; the two oxide coupling layers are made of any one of magnesium oxides and magnesium oxides containing at least one of iron, cobalt, nickel, zinc and boron; and the magnetic insertion layer contains at least one of iron, cobalt, and nickel.

2. The magnetic tunnel junction according to claim 1, wherein the free layer is sandwiched between magnesium oxide film layers.

3. The magnetic tunnel junction according to claim 2, wherein the magnetic insertion layer contains at least one non-magnetic element of boron, silicon, aluminum, tungsten, tantalum, hafnium, zirconium, niobium, molybdenum, titanium, vanadium, chromium, palladium, and platinum; and a thickness of the magnetic insertion layer is less than 1 nanometer.

4. The magnetic tunnel junction according to claim 2, wherein a top view of the free layer is any one of a circle with a diameter between 20 nanometers and 50 nanometers and a non-circle with an area between 310 square nanometers and 1960 square nanometers; and coupling energy between any adjacent ferromagnetic film layers of the ferromagnetic film layers is not greater than 0.5 mJ/m².

5. The magnetic tunnel junction according to claim 2, wherein a thickness of the coupling superposition layer is larger than that of an insulating tunneling layer connecting the free layer and a fixed layer of the magnetic tunnel junction.

6. The magnetic tunnel junction for a magnetic memory chip according to any one of claims 1 to 5, wherein the material, composition and thickness of the ferromagnetic film layers at different positions are either the same or different; the material, composition and thickness of the coupling superposition layers at different positions are either the same or different; the material, composition and thickness of the oxide coupling layers at different positions are either the same or different; and the material, composition and thickness of the magnetic insertion layers at different positions are either the same or different.

7. A method for manufacturing the magnetic tunnel junction for a magnetic memory chip according to claim 2, comprising the following characteristic steps:
(1.1) preparing a first magnesium oxide film layer;
(1.2) preparing a first ferromagnetic film layer with a magnetization direction perpendicular to a film surface on one side of the first magnesium oxide film layer;
(1.3) preparing a first oxide coupling layer on an adjacent side of the first ferromagnetic film layer opposite the first magnesium oxide film layer;
(1.4) preparing a first magnetic insertion layer on an adjacent side of the first oxide coupling layer opposite the first ferromagnetic film layer;
(1.5) preparing a second oxide coupling layer on an adjacent side of the first magnetic insertion layer opposite the first oxide coupling layer;
(1.6) preparing a second ferromagnetic film layer with a magnetization direction perpendicular to a film surface on an adjacent side of the second oxide coupling layer opposite the first magnetic insertion layer; and
(1.7) preparing a second magnesium oxide film layer on an adjacent side of the second ferromagnetic film layer opposite the second oxide coupling layer.

8. The method for manufacturing a magnetic tunnel junction according to claim 7, wherein after step (1.6), steps (1.3) to (1.6) are repeated to form a structure in which a plurality of coupling superposition layers are alternately superimposed with a plurality of ferromagnetic film layers.

9. The method for manufacturing a magnetic tunnel junction according to claims 7 and 8, wherein the ferromagnetic film layers are formed by any one of film deposition methods of co-sputtering with other targets, alternating sputtering with other targets, and sputtering after directly adding cobalt and iron into other targets for doping.

10. The method for manufacturing a magnetic tunnel junction according to claims 7 and 8, wherein the oxide coupling layers are formed by any one of film deposition methods of co-sputtering with other targets, alternating sputtering with other targets, and sputtering after directly adding cobalt and iron into other targets for doping.

11. The method for manufacturing a magnetic tunnel junction according to claims 7 and 8, wherein the magnetic insertion layers are formed by any one of film deposition methods of co-sputtering with other targets, alternating sputtering with other targets, and sputtering after directly adding cobalt and iron into other targets for doping.
